(19) United States
(12) Patent Application Publication
(10) Pub. No.: US 2016/0351819 A1
(43) Pub. Date: Dec. 1, 2016

(54) ORGANIC LIGHT EMITTING DIODE AND ORGANIC LIGHT EMITTING DIODE DISPLAY INCLUDING THE SAME

(71) Applicant: Samsung Display Co., Ltd.

(72) Inventors: Dong Chan Kim, Gunpo-si (KR); Won Jong Kim, Suwon-si (KR); Eung Do Kim, Seoul (KR); Dong Kyu Seo, Hwaseong-si (KR); Ji Hye Lee, Incheon (KR); Da Hea Im, Incheon (KR); Sang Hoon Yim, Suwon-si (KR); Won Suk Han, Yongin-si (KR)

(21) Appl. No.: 15/004,638

(22) Filed: Jan. 22, 2016

(30) Foreign Application Priority Data
Jun. 1, 2015 (KR) 10-2015-0077495

(51) Int. Cl. H01L 51/00; H01L 27/32

(52) U.S. Cl. CPC H01L 51/0061; H01L 27/3248; H01L 27/3206; H01L 51/5056

(57) ABSTRACT

An organic light emitting diode includes: a first electrode and a second electrode that face each other; a middle layer on the first electrode; a hole transport layer on the middle layer; and an emission layer between the hole transport layer and the second electrode, wherein the middle layer includes a bipolar material formed by combining a first material including at least selected from a group 1 element, a group 2 element, a lanthanide metal, with a second material including a halogen element.

### CROSS-REFERENCE TO RELATED APPLICATION

This application claims priority to and the benefit of Korean Patent Application No. 10-2015-0077495 filed in the Korean Intellectual Property Office on Jun. 1, 2015, the entire contents of which are incorporated herein by reference.

### BACKGROUND

1. Field

Embodiments of the present disclosure relate to an organic light emitting diode and an organic light emitting diode display including the same.

2. Description of the Related Art

Recent trends toward lightweight and thin personal computers and televisions sets also require lightweight and thin display devices, and flat panel displays satisfying such requirements are being substituted for cathode ray tubes (CRTs). However, liquid crystal displays, which are a light receiving element, utilize a separate backlight and have limitations in response speed, viewing angle, and the like.

An organic light emitting device, which is a self-emitting display element having features of a wide viewing angle, excellent contrast, and a fast response time, has greatly attracted attention as a display device capable of overcoming the aforementioned limitations.

The organic light emitting display device includes an organic light emitting diode for light emission, and the organic light emitting diode forms excitons from a combination of electrons injected from one electrode and holes injected from another electrode in an emission layer, and the excitons emit energy such that light is emitted.

However, certain organic light emitting devices have problems of a high driving voltage, high light emission brightness, low luminance and light emission efficiency, and a short life span.

The above information disclosed in this Background section is only to enhance the understanding of the background of the present disclosure, and therefore it may contain information that does not form the prior art that is already known in this country to a person of ordinary skill in the art.

### SUMMARY

Embodiments of the present disclosure have been made in an effort to provide an organic light emitting element that can provide smooth hole injection by adjusting a work function through halogenated treatment of a surface of an electrode of the organic light emitting element.

An organic light emitting diode according to an exemplary embodiment of the present disclosure includes: a first electrode and a second electrode that face each other; a middle layer provided on the first electrode; a hole transport layer provided on the middle layer; and an emission layer provided between the hole transport layer and the second layer, wherein the middle layer includes a bipolar material formed by combining a first material including at least one selected from a group 1 element, a group 2 element, and a lanthanide metal, with a second material including a halogen element.

The middle layer may include at least one selected from an iodinated group 1 element, an iodinated group 2 element, an iodinated lanthanide metal, and an iodinated transition metal.

The middle layer may include at least one compound selected from LiI, NaI, KI, RbI, CsI, CuI, AgI, TlI, and CoI₂.

The thickness of the middle layer may be about 10 nm to about 20 nm.

The organic light emitting diode may further include a hole injection layer provided between the middle layer and the hole transport layer, wherein the hole injection layer and the hole transport layer may include an organic material.

A work function of the first electrode may be about 5.0 eV to about 7.0 eV.

A work function difference between the first electrode and the hole transport layer may be less than or equal to about 0.5 eV.

An organic light emitting diode display according to another exemplary embodiment of the present disclosure includes: a substrate; a thin film transistor provided on the substrate; and an organic light emitting diode coupled or connected to the thin film transistor, wherein the organic light emitting diode includes: a first electrode and a second electrode facing each other; a middle layer on the first electrode; a hole transport layer on the middle layer; and an emission layer on the hole transport layer, and the middle layer includes a bipolar material formed by combining a first material including at least one selected from a group 1 element, a group 2 element, and a lanthanide metal, with a second material including a halogen element.

The middle layer may include at least one selected from an iodinated group 1 element, an iodinated group 2 element, an iodinated lanthanide metal, and an iodinated transition metal.

A work function of the first electrode may be about 5.0 eV to about 7.0 eV.

A work function difference between the first electrode and the hole transport layer may be less than or equal to about 0.5 eV.

The organic light emitting diode may further include a hole injection layer between the middle layer and the hole transport layer, wherein the hole injection layer and the hole transport layer may each include an organic material.

The emission layer may include a red emission layer, a green emission layer, and a blue emission layer, and may further include an assistant layer at a lower end of the blue emission layer.

The emission layer may further include a red resonance assistant layer at a lower end of the red emission layer and a green resonance assistant layer at a lower end of the green emission layer.

The assistant layer may include a compound represented by Chemical Formula 1:

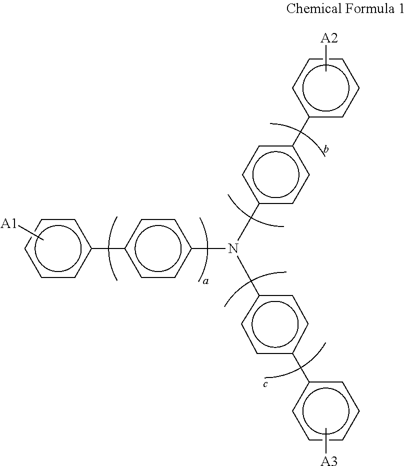

wherein in Chemical Formula 1, A1, A2, and A3 are each independently selected from an alkyl group, an aryl group, carbazole, dibenzothiophene, dibenzofuran (DBF), and biphenyl, and a, b, and c are each independently selected from positive numbers of zero to four.

The assistant layer may include a compound represented by Chemical Formula 2:

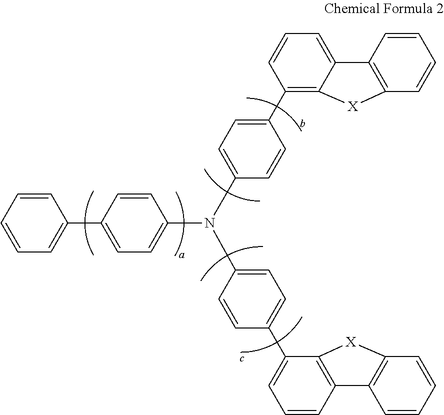

wherein, in Chemical Formula 2, a is selected from 0 to 3, and b and c are each independently selected from 0 to 3, X is selected from O, N, or S, and each X is the same as or different from each other.

According to an exemplary embodiment of the present disclosure, two (e.g., both) surfaces of an electrode are halogenated such that a work function of the surfaces can be adjusted, thereby improving hole injection characteristics.

### BRIEF DESCRIPTION OF THE DRAWINGS

The accompanying drawings, together with the specification, illustrate embodiments of organic light emitting displays of the present disclosure, and, together with the description, serve to explain principles of embodiments of the organic light emitting displays.

FIG. 1 illustrates a cross-sectional view of an organic light emitting display according to an exemplary embodiment of the present disclosure.

FIG. 2 illustrates an enlarged cross-sectional view of an organic light emitting element of the organic light emitting display of FIG. 1.

FIG. 3 illustrates a cross-sectional view of an exemplary variation of a part of the organic light emitting element of FIG. 2 according to an exemplary variation.

FIG. 4 illustrates a cross-sectional view of an exemplary variation of a part of the organic light emitting element of FIG. 2.

### DETAILED DESCRIPTION

Embodiments of the present disclosure will be described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

In the drawings, the thickness of layers, films, panels, regions, etc., may be exaggerated for clarity. Like reference numerals designate like elements throughout the specification. It will be understood that when an element such as a layer, film, region, or substrate is referred to as being “on,” “coupled to,” or “connected to” another element, the layer, film, region, or substrate can be directly on, directly coupled to, or directly connected to the other element or intervening elements may also be present. In contrast, when an element is referred to as being “directly on” another element, there are no intervening elements present. In addition, it will also be understood that when an element or layer is referred to as being “between” two elements or layers (e.g., an emission layer between a hole transport layer and a second layer), it can be the only element or layer between the two elements or layers, or one or more intervening elements or layers may also be present.

It will be understood that, although the terms “first,” “second,” “third,” etc., may be used herein to describe various elements, components, regions, layers and/or sections (e.g., a first contact hole and a second contact hole), these elements, components, regions, layers and/or sections should not be limited by these terms. These terms are used to distinguish one element, component, region, layer or section from another element, component, region, layer or section (e.g., to distinguish one contact hole from another contact hole). Thus, a first element, component, region, layer or section described below could be termed a second element, component, region, layer or section, without departing from the spirit and scope of the present invention.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below (e.g., as described herein, a diving semiconductor layer 137 may be above or below a substrate buffer layer 126). The device may be otherwise oriented (e.g., rotated 90 degrees or at other orientations) and the spatially relative descriptors used herein should be interpreted accordingly.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, acts, operations, elements, and/or components, but do not preclude the presence or addition of one or more other features, integers, acts, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the terms “substantially,” “about,” and similar terms are used as terms of approximation and not as terms of degree, and are intended to account for the inherent deviations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively. Also, the term “exemplary” is intended to refer to an example or illustration.

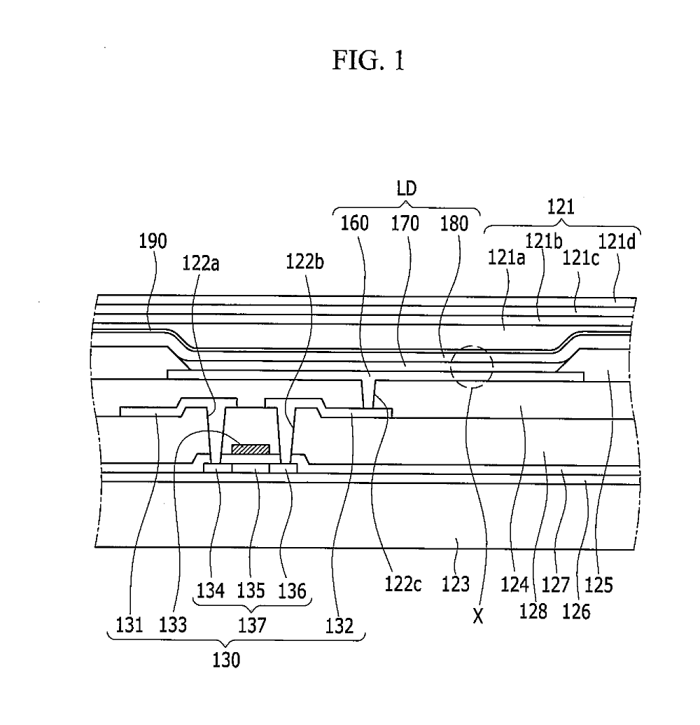

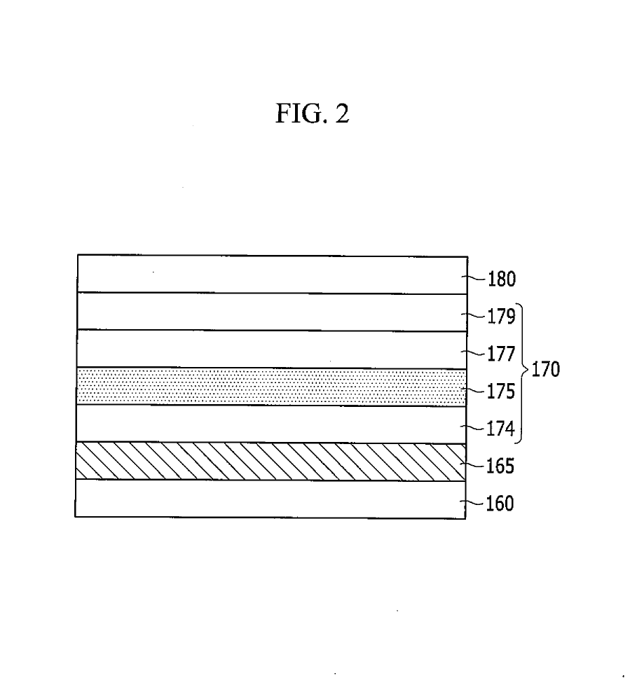

FIG. 1 illustrates a cross-sectional view of an organic light emitting display according to an exemplary embodiment of the present disclosure. FIG. 2 illustrates an enlarged cross-sectional view of the organic light emitting display of FIG. 1.

A substrate 123 of FIG. 1 may, for example, be made of an inorganic material such as glass, an organic material such as polycarbonate, polymethyl methacrylate, polyethylene terephthalate, polyethylene naphthalate, polyamide, polyethersulfone, polyimide, or, a combination thereof, or a silicon wafer. As used herein, the terms “combination thereof” and “combinations thereof” may refer to a chemical combination (e.g., an alloy or chemical compound), a mixture, or a laminated structure of components.

A substrate buffer layer 126 may be provided on the substrate 123. The substrate buffer layer 126 prevents or reduces permeation of an impurity element and provides a flat surface.

In this case, the substrate buffer layer 126 may be made of various suitable materials that can provide the above-stated functions. For example, one of a silicon nitride (SiNx) layer, a silicon oxide (SiOx) layer, and a silicon oxynitride (SiOxNy) layer may be used as the substrate buffer layer 126. However, the substrate buffer layer 126 is not a required element or configuration, and may be omitted depending on a kind of substrate 123 and a process condition.

A driving semiconductor layer 137 may be formed above the substrate buffer layer 126. The driving semiconductor layer 137 may be made of a material including polysilicon. In some embodiments, the driving semiconductor layer 137 includes a channel region 135 in which impurities are not doped, and a source region 134 and a drain region 136 in which the impurities are doped at both sides of the channel region 135. In this case, the doped ion materials may be P-type impurities such as boron (B), and/or B₂H₆, which are mainly used. Here, the impurities may vary or be selected according to a kind of thin film transistor.

A gate insulating layer 127 made of a silicon nitride SiNx or a silicon oxide SiOx is formed on the driving semiconductor layer 137. A gate wire including a driving gate electrode 133 is formed on the gate insulating layer 127. In addition, the driving gate electrode 133 is formed to overlap at least a part of the driving semiconductor layer 137, for example, the channel region 135.

An interlayer insulating layer 128 covering the driving gate electrode 133 is formed on the gate insulating layer 127. A first contact hole 122a and a second contact hole 122b that expose the source area 134 and the drain area 136 of the driving semiconductor 137 are formed in the gate insulating layer 127 and the interlayer insulating layer 128. Like the gate insulating layer 127, the interlayer insulating layer 128 may be made of a material such as a silicon nitride SiNx or a silicon oxide SiOx.

In some embodiments, a data wire including a driving source electrode 131 and a driving drain electrode 132 may be provided on the interlayer insulating layer 128. Further, in some embodiments, the driving source electrode 131 and the driving drain electrode 132 are respectively coupled or connected with the source area 134 and the drain area 136 of the driving semiconductor layer 137 through the first contact hole 122a and the second contact hole 122b respectively formed in the interlayer insulating layer 128 and the gate insulating layer 127.

As described herein, the driving thin film transistor 130 may include the driving semiconductor layer 137, the driving gate electrode 133, the driving source electrode 131, and the driving drain electrode 132. The configuration of the driving thin film transistor 130 is not limited to the aforementioned example, and may be variously modified to any suitable configuration available in the art or which may be easily implemented by those skilled in the art.

In some embodiments, a planarization layer 124 covering the data wire is formed on the interlayer insulating layer 128. The planarization layer 124 serves to remove and planarize a step in order to increase emission efficiency of the organic light emitting element to be formed thereon. Further, the planarization layer 124 has a third contact hole 122c exposing a part of the drain electrode 132.

The planarization layer 124 may be made of one or more materials selected from a polyacrylate resin, an epoxy resin, a phenolic resin, a polyamide resin, a polyimide resin, an unsaturated polyester resin, a polyphenylene ether resin, a polyphenylene sulfide resin, and benzocyclobutene (BCB).

Here, an exemplary embodiment according to the present disclosure is not limited to the aforementioned structure, and in some cases, one or more selected from the planarization layer 124 and the interlayer insulating layer 128 may be omitted.

In some embodiments, a first electrode of the organic light emitting element, e.g., a pixel electrode 160, is formed on the planarization layer 124. For example, the organic light emitting diode device includes a plurality of pixel electrodes 160 which are respectively disposed for each of a plurality of pixels. In some embodiments, the plurality of pixel electrodes 160 are spaced apart from each other. The pixel electrode 160 is coupled or connected to the drain electrode 132 through a third contact hole 122c of the planarization layer 124.

Further, a pixel defining layer 125 having an opening exposing the pixel electrode 160 is formed on the planarization layer 124. For example, the pixel defining layer 125 has a plurality of openings, each of the openings corresponding to a respective one of the pixels. In this case, the light-emitting element layer 170 may be formed for each opening formed by the pixel defining layer 125. Accordingly, a pixel area in which each light-emitting element layer 170 is formed by the pixel defining layer 125 may be defined.

In this case, the pixel electrode 160 is disposed to correspond to the opening of the pixel defining layer 125. However, the pixel electrode 160 is not necessarily disposed only in the opening of the pixel defining layer 125, but may be disposed below the pixel defining layer 125 such that a part of the pixel electrode 160 overlaps the pixel defining layer 125.

The pixel defining layer 125 may be made of a resin, such as a polyacrylate resin and/or a polyimide, a silica-based inorganic material, and/or the like.

In some embodiments, a light-emitting element layer 170 is formed on the pixel electrode 160. Hereinafter a structure of the light-emitting element layer 170 will be described in more detail.

A second electrode, e.g., a common electrode 180, may be formed on the light-emitting element layer 170. As described herein, an organic light emitting element LD may include the pixel electrode 160, the light-emitting element layer 170, and the common electrode 180.

In some embodiments, the pixel electrode 160 and the common electrode 180 may be made of a transparent conductive material or a transflective or reflective conductive material. According to the kind of materials forming the pixel electrode 160 and/or the common electrode 180, the organic light emitting diode device may be a top emission type (or kind), a bottom emission type (or kind), or a double-sided emission type (or kind).

In some embodiments, an overcoat 190 covering and protecting the common electrode 180 may be formed as an organic layer on the common electrode 180.

In addition, a thin film encapsulation layer 121 may be formed on the overcoat 190. The thin film encapsulation layer 121 encapsulates and protects the organic light emitting element LD and a driving circuit part formed on the substrate 123 from the external environment.

In some embodiments, the thin film encapsulation layer 121 includes organic encapsulation layers 121a and 121c, and inorganic encapsulation layers 121b and 121d, which are alternately laminated. In FIG. 1, for example, a case where two organic encapsulation layers 121a and 121c and two inorganic encapsulation layers 121b and 121d are alternately laminated to configure the thin film encapsulation layer 121 is illustrated, but the present disclosure is not limited thereto.

Hereinafter, an organic light emitting element according to an exemplary embodiment of the present disclosure will be described with reference to FIG. 2.

Referring to FIG. 2, the organic light emitting element (part X in FIG. 1) according to an exemplary embodiment of the present disclosure includes a structure in which the first electrode 160, a middle layer 165, a hole transport layer 174, an emission layer 175, an electron transport layer 177, an electron injection layer 179, and the second electrode 180 are sequentially layered.

When the first electrode 160 is an anode, a material selected from materials having a high work function may be selected to form the first electrode 160 for easy hole injection. The first electrode 160 may be a transparent electrode or an opaque electrode (e.g., a reflective electrode). When the first electrode 160 is a transparent electrode, it may be made of indium-tin oxide (ITO), indium-zinc oxide (IZO), tin oxide (SnO2), zinc oxide (ZnO), or a conductive oxide or combinations thereof, or a metal such as aluminum, silver, and/or magnesium, with a small thickness. When the first electrode 160 is an opaque electrode, it may be made of a metal such as aluminum, silver, and/or magnesium.

The first electrode 160 may be formed to be a two or more-layer structure including different kinds of materials. For example, the first electrode 160 may be formed to have a structure in which indium-tin oxide (ITO)/silver (Ag)/indium-tin oxide (ITO) are sequentially stacked.

The first electrode 160 may be formed by sputtering or vacuum deposition.

The middle layer 165 is provided on the first electrode 160. The middle layer 165 is formed on the first electrode 160 to reduce an electron injection barrier by increasing a work function of the first electrode 160 and to smooth or smoothen the hole injection into the hole transport layer 174.

For example, the middle layer 165 serves to reduce a work function difference between the first electrode 160 and the hole transport layer 174 for smooth hole injection to the emission layer 175 from the first electrode 160.

In an exemplary embodiment of the present disclosure, the middle layer 165 may be a dipolar material formed of a first material including at least one selected from group 1 elements, group 2 elements, lanthanum-based metals, and transition metals, and a second material including at least one selected from halogen elements.

For example, the middle layer 165 according to the present exemplary embodiment may include at least one selected from iodinated group 1 elements, iodinated group 2 elements, iodinated lanthanum-based metals, and iodinated transition metals. For example, the middle layer 165 may be (include) at least one compound selected from LiI (lithium iodide), NaI (sodium iodide), KI (potassium iodide), RbI (rubidium iodide), CsI (caesium iodide), CuI (copper iodide), AgI (silver iodide), TlI (thallium iodide), and CoI₂ (cobalt (II) iodide), but it is not limited thereto.

In the case that a halogenated group 1 element, a halogenated group 2 element, a halogenated lanthanum-based metal, or a halogenated transition metal compound is formed on the first electrode 160, a work function of the first electrode 160 is, for example, about 5.0 eV to about 7.0 eV. Compared to a case in which a work function of an ITO electrode where no middle layer 165 is formed is about 4.5 eV to about 4.8 eV, the first electrode 160 according to an exemplary embodiment of the present disclosure has an increased work function. Thus, a work function difference with the hole transport layer 174 provided on the first electrode 160 is reduced. For example, in some embodiments, a work function difference between the first electrode 160 and the hole transport layer 174 is, for example, less than or equal to about 0.5 eV.

In the present exemplary embodiment, the middle layer 165 may be formed using various suitable methods, such as a thermal evaporation method, a sputtering method, a chemical vapor deposition (CVD) method, an atomic layer deposition (ALD), a chemical solution deposition (CSD) method, and/or the like.

For example, the middle layer 165 according to the present exemplary embodiment is deposited by the thermal evaporation method. The thermal evaporation method is a vacuum deposition method, and when the thermal evaporation method is used, purity of a deposition material is excellent and thus efficiency uniformity can be excellent, and surface roughness is excellent as compared to a layer formed by a gas-based plasma deposition method. In some embodiments, when the thermal deposition method is used, a deposition thickness is very small and thus a variation range of the work function can be very precisely adjusted. Further, in the present exemplary embodiment, a metal (e.g., Sn, In, and/or the like) other than the halogen included in the middle layer 165 can be prevented from being spread into a hole transport layer (or such spread can be reduced), which is an organic material.

In some embodiments, the thickness of the middle layer 165 is between about 10 nm to about 20 nm. When the thickness of the middle layer 165 is less than 10 nm, the work function of the first electrode 160 cannot be adjusted (e.g., cannot be suitably adjusted) and when the thickness of the middle layer 165 exceeds 20 nm, a problem may occur in hole injection into the hole transport layer 174 from the first electrode 160 due to the middle layer 165.

The hole transport layer 174 is disposed on the middle layer 165. The hole transport layer 174 may serve to smoothly transport holes transmitted from a hole injection layer 172. The hole transport layer 174 may include an organic material. For example, the hole transport layer 174 may include NPD (N,N-dinaphthyl-N,N′-diphenyl benzidine), TPD (N,N′-bis-(3-methylphenyl)-N,N-bis-(phenyl)-benzidine), s-TAD, MTDATA (4,4′,4″-tris(N-3-methylphenyl-N-phenyl-amino)-triphenylamine), and/or the like, but is not limited thereto.

In some embodiments, the thickness of the hole transport layer 174 may be about 15 nm to about 25 nm. For example, the thickness of the hole transport layer 174 may be about 20 nm. In the present exemplary embodiment, a hole injection material is included in the hole transport layer 174 as a modification of the hole transport layer 174, and thus the hole transport/injection layers may be formed as a single layer.

The emission layer 175 is disposed on the hole transport layer 174. The emission layer 175 includes an emission material that represents (e.g., emits) a set or specific color (e.g., a set color of light). For example, the emission layer 175 may display (e.g., emit) a basic color such as blue, green, or red, or a combination thereof (e.g., blue light, green light, red light, or a combination thereof).

The thickness of the emission layer 175 may be about 10 nm to about 50 nm. The emission layer 175 includes a host and a dopant. The emission layer 175 may include a material that emits red light, green light, blue light, and/or white light, and may be formed using a phosphorescent and/or fluorescent material.

When the emission layer 175 emits red light, the emission layer 175 may include a host material that includes CBP (carbazole biphenyl) or mCP (1,3-bis(carbazol-9-yl), and may be formed of a phosphorescent material including at least one selected from the group consisting of PIQIr(acac) (bis(1-phenylisoquinoline)acetylacetonate iridium), PQIr(acac) (bis(1-phenylquinoline)acetylacetonate iridium), PQIr(tris(1-phenylquinoline)iridium), and PtOEP (octaethylporphyrin platinum), or a fluorescent material including PBD:Eu(DBM)3(Phen) or perylene, but the present disclosure is not limited thereto.

When the emission layer 175 emits green light, the emission layer 175 includes a host material including CBP or mCP, and may be made of a phosphorescent material including a dopant material including Ir(ppy)3(fac-tris(2-phenylpyridine)iridium) or a fluorescent material including Alq3(tris(8-hydroxyquinolino)aluminum), but the present disclosure is not limited thereto.

When the emission layer 175 emits blue light, the emission layer 175 includes a host material including CBP or mCP, and may be made of a phosphorescent material including a dopant that includes (4,6-F2ppy)2Irpic. Alternatively or additionally, the emission layer 175 may be made of a fluorescent material including at least one selected from the group consisting of spiro-DPVBi, spiro-6P, distyrylbenzene (DSB), distyrylarylene (DSA), a PFO-based polymer, and a PPV-based polymer, but the present disclosure is not limited thereto.

The electron transport layer 177 is disposed on the emission layer 175. The electron transport layer 177 may transfer electrons from the second electrode 180 to the emission layer 175. In addition, the electron transport layer 177 can prevent holes injected from the first electrode 160 from moving to the second electrode 180 through the emission layer 175 (or the electron transport layer 177 can reduce such movement). For example, the electron transport layer 177 helps holes and electrons bond (e.g., recombine) in the emission layer 175 by functioning as a hole blocking layer.

In some embodiments, the electron transport layer 177 may include an organic material. For example, the electron transport layer 177 may be made of any one or more selected from the group consisting of Alq3 (tris(8-hydroxyquinolino)-aluminum), PBD, TAZ, spiro-PBD, BAlq, and SAlq, but the present disclosure is not limited thereto.

The electron injection layer 179 is disposed on the electron transport layer 177. The electron injection layer 179 serves to enhance electron injection to the electron transport layer 177 from the second electrode 180.

The thickness of the electron injection layer 179 may be about 1 nm to about 50 nm.

The electron injection layer 179 according to an exemplary embodiment of the present disclosure includes a metal-based halogen bipolar material. In some embodiments, the electron injection layer 179 may be a bipolar material formed by combining a group 1 element, a group 2 element, a lanthanide metal such as Li, Na, K, Rb, Cs, Fr, Be, Mg, Ca, Sr, Ba, Ra, La, Yb, Lu, Tm, Ce, Pr, and Nd with a material selected from halogen materials such as F, Cl, Br, and I.

The electron injection layer 179 may be formed of a single layer of a metal-based halogen bipolar material, or may have a double-layered structure including metal and a metal-based halogen material (e.g., a double-layered structure including a metal layer and a metal-based halogen material layer).

The electron injection layer 179 may be formed using a sputtering method.

The second electrode 180 is provided on the electron injection layer 179. When the second electrode 180 is a cathode, the second electrode 180 may include a material having a small work function for easy electron injection. For example, the material may be a metal, such as magnesium, calcium, sodium, potassium, titanium, indium, yttrium, lithium, gadolinium, aluminum, silver, tin, lead, cesium, barium, and/or the like, or an alloy thereof, or a multi-layered structure material, such as LiF/Al, LiO2/Al, LiF/Ca, LiF/Al, and/or BaF2/Ca, but the present disclosure is not limited thereto.

When the second electrode 180 is formed by alloys, an alloy ratio of the alloys is controlled based on a temperature of a deposition source, an atmosphere (e.g., the composition of the atmosphere), a degree of vacuum, and/or the like, and an appropriate or suitable alloy ratio may be selected.

The second electrode 180 may be formed of two or more layers.

In an exemplary embodiment of the present disclosure, the first electrode 60 indicates a work function increased due to the middle layer 165 formed on the first electrode 160. This will be described in more detail with reference to Table 1. Table 1 shows the work function of the first electrode 160, emission efficiency, and life-span of the light emitting display in the case that the middle layer 165 is formed on the first electrode 160 according to an exemplary embodiment of the present disclosure.

In this case, exemplary embodiment 1 and exemplary embodiment 2 are cases in which a middle layer 165 is formed of CuI, which is a transition metal-based halogen bipolar material, on a first electrode 160 formed of Ag/ITO.

Meanwhile, Comparative Example 1 is a case in which no middle layer 165 is formed (e.g., no middle layer 165 is formed on the first electrode 160).

TABLE 1

| | Work | Driving | Emission | Life-span |
|---|---|---|---|---|
| | function | voltage (V) | efficiency (cd/A) | 97% |
| Comparative | 4.8 eV | 4.6 | 146.7 | 151 h |
| Example 1 | | | | |
| Exemplary | 5.0 eV | 4.4 | 151.0 | 170 h |
| embodiment 1 | | | | |
| Exemplary | 5.1 eV | 4.2 | 157.8 | 200 h |
| embodiment 2 | | | | |

Emission efficiency implies (refers to) initial luminance, and life-span implies (refers to) the time taken for displaying luminance reduced to 97% from the initial emission luminance (100%).

Referring to Table 1, compared to the comparative example, exemplary embodiment 1 and exemplary embodiment 2 respectively have work functions of greater than or equal to about 5.0 eV, and have higher emission efficiency. Further, the life-span of the organic light emitting element is also increased. This is because the first electrode 160, on which the middle layer 165 is provided, has an increased work function such that the hole injection rate to the hole injection layer or the hole transport layer is increased, thereby increasing the combination with the electrons (e.g., the combination of the holes with the electrons). On the contrary, when the hole injection rate is decreased, the combination between the holes and the electrodes is decreased and the life-span of the organic light emitting element is reduced due to the remaining holes and electrons from the combination.

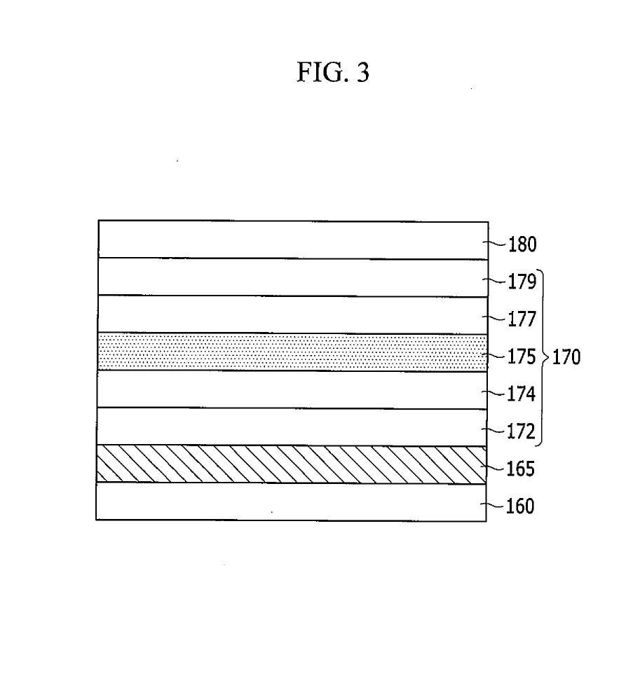

FIG. 3 illustrates a cross-sectional view of a partial exemplary variation of the organic light emitting element of FIG. 2.

Referring to FIG. 3, a hole injection layer 172 is added to the light-emitting layer 170 of the exemplary embodiment of FIG. 2. In the present exemplary embodiment, the hole injection layer 172 is provided between the hole transport layer 174 and the middle layer 165. The hole injection layer 172 eases (e.g., improves) injection of holes to the hole transport layer 174 from the first electrode 160 on which the middle layer 165 is disposed. In the present exemplary embodiment, the hole injection layer 172 may be formed of an organic layer, but may include a bipolar material formed by combining a metal or non-metal having a work function of greater than or equal to 4.3 eV and halogen.

The metal or non-metal having a work function of greater than or equal to about 4.3 eV may be one selected from the group consisting of Ag, Au, B, Be, C, Co, Cr, Cu, Fe, Hg, Ir, Mo, Nb, Ni, Os, Pd, Pt, Re, Rh, Ru, Sb, Se, Si, Sn, Ta, Te, Ti, V, W, and Zn.

In the present exemplary embodiment, the middle layer 165 is disposed on the first electrode 160. The middle layer 165 is formed on the first electrode 160 to reduce an electron injection barrier by increasing a work function of the first electrode 160 and to smoothen (e.g., improve) hole injection into the hole injection layer 172 and the hole transport layer 174.

For example, the middle layer 165 serves to reduce a work function difference between the first electrode 160 and the hole injection layer 172 or the hole transport layer 174 for smooth hole injection to the emission layer 175 from the first electrode 160.

In addition to the above-described difference, the contents described with reference to FIG. 2 are applicable to the exemplary embodiment of FIG. 3.

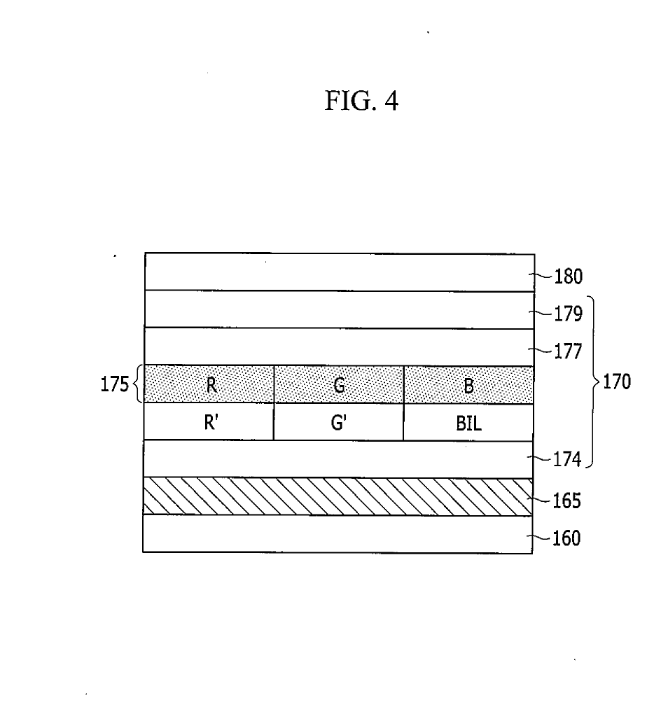

FIG. 4 illustrates a cross-sectional view of a partial exemplary variation of the organic light emitting diode of FIG. 2.

Referring to FIG. 4, the emission layer 175 of the organic light emitting diode in FIG. 2 is deformed (e.g., modified) in the present exemplary variation. For example, an emission layer 175 of the present exemplary embodiment includes a red emission layer R, a green emission layer G, and a blue emission layer B, and an assistant layer BIL may be provided at a lower end of the blue emission layer B to increase emission efficiency of the blue emission layer B.

The red emission layer R may be about 30 nm to about 50 nm thick, the green emission layer G may be about 10 nm to about 30 nm thick, and the blue emission layer B may be about 10 nm to about 30 nm thick. The assistant layer BIL provided in a lower end of the blue emission layer B may be less than or equal to about 20 nm thick. The assistant layer BIL serves to improve efficiency of the blue emission layer B by adjusting a hole charge balance. The assistant layer BIL may include a compound represented by Chemical Formula 1.

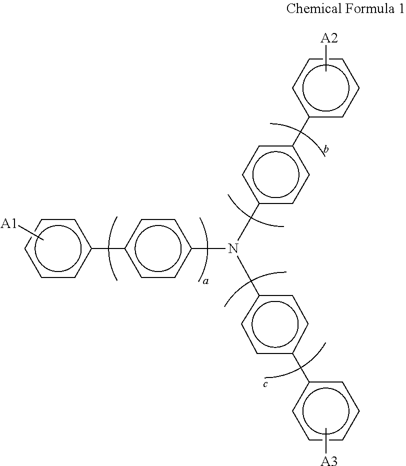

In Chemical Formula 1, A1, A2, and A3 may each be independently selected from an alkyl group, an aryl group, carbazole, dibenzothiophene, dibenzofuran (DBF), and biphenyl, and a, b, and c may each be independently selected from positive numbers of zero to four.

Examples of the compounds represented by Chemical Formula 1 include the following Chemical Formulas 1-1, 1-2, 1-3, 1-4, 1-5, and 1-6.

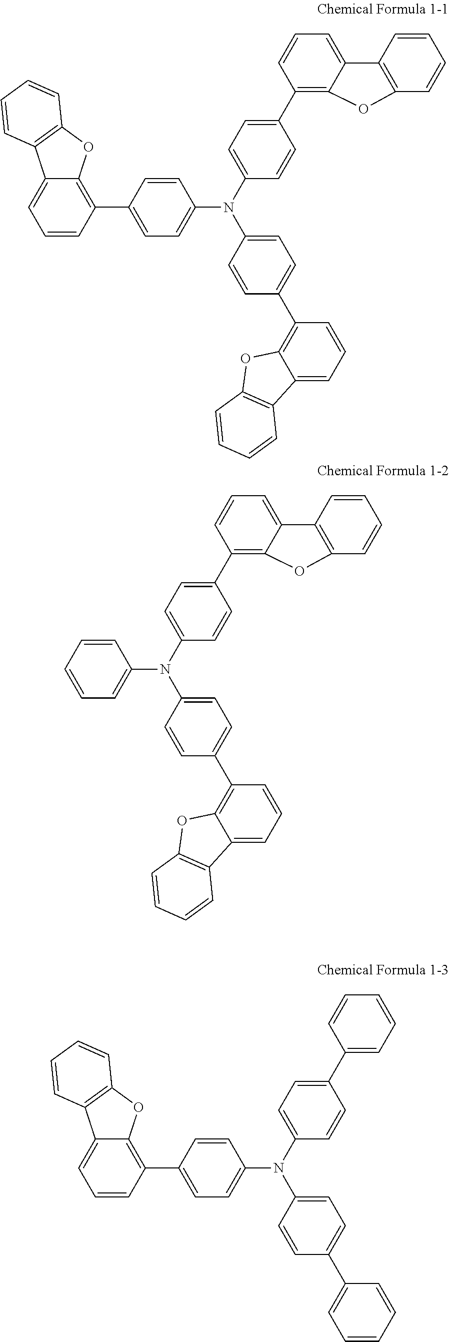

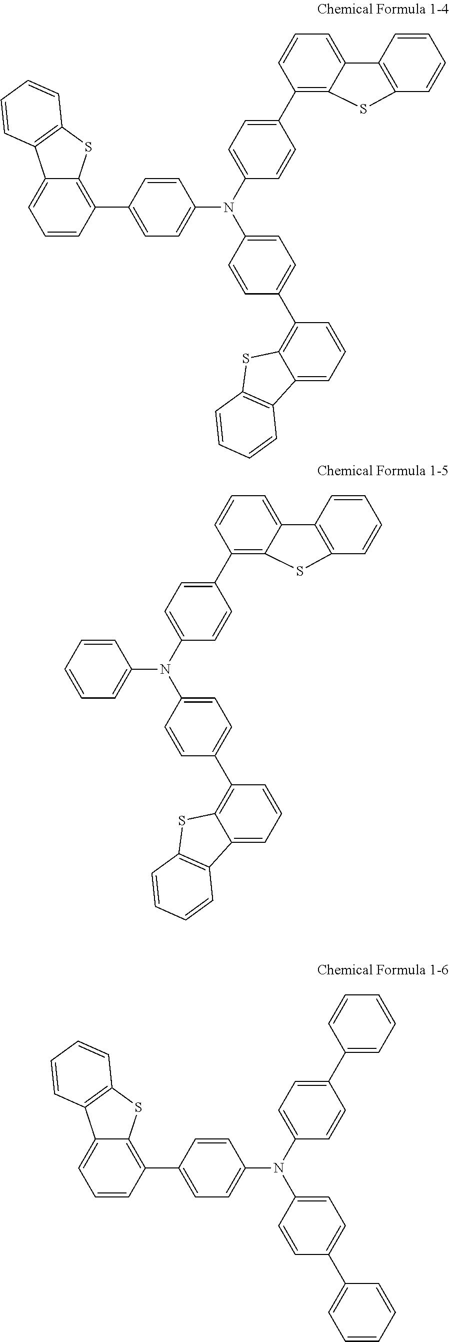

In another exemplary embodiment, the assistant layer BIL may include a compound represented by Chemical Formula 2.

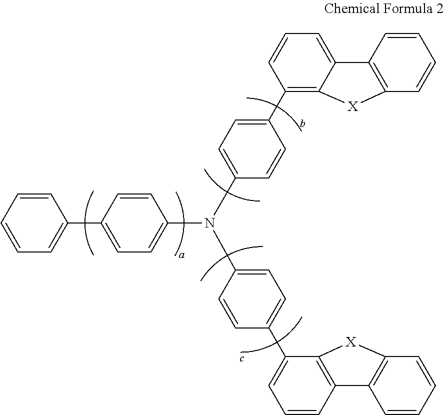

In Chemical Formula 2, a may be 0 to 3, b and c may each independently be 0 to 3, X may be selected from O, N, or S, and each X may be the same or different from each other.

Examples of the compound represented by Chemical Formula 2 include Chemical Formulas 2-1, 2-2, 2-3, 2-4, 2-5, and 2-6.

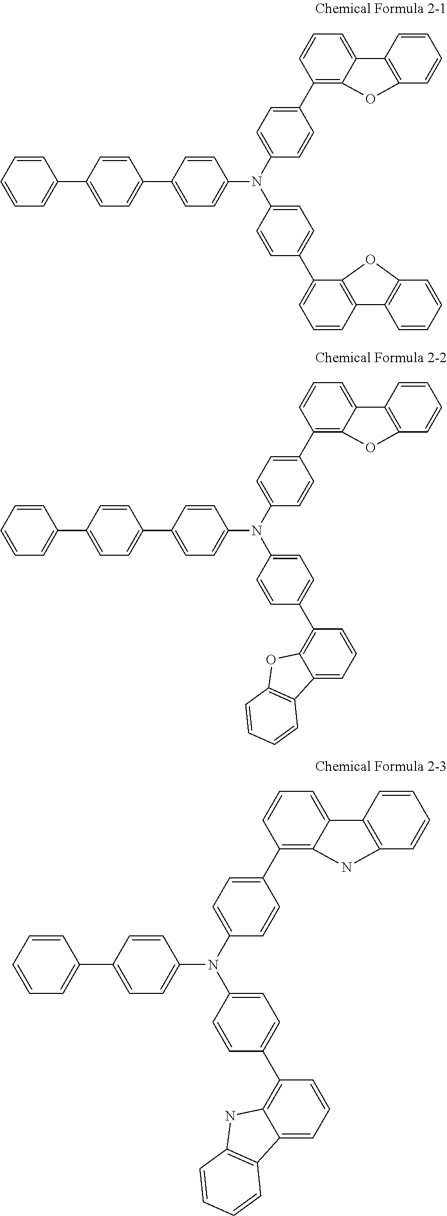 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(N(c3ccc(-c4cccc5c4[nH]c4ccccc45)cc3)c3ccc(-c4cccc5c4[nH]c4ccccc45)cc3)cc2)cc1]

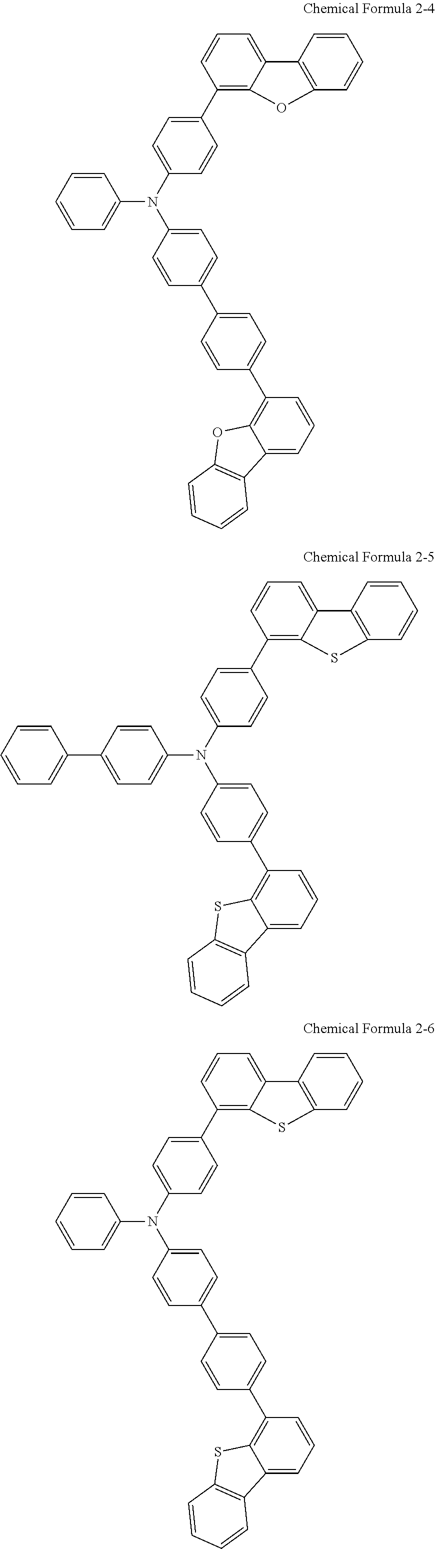 [SMILES: c1ccc(N(c2ccc(-c3ccc(-c4cccc5c4oc4ccccc45)cc3)cc2)c2ccc(-c3cccc4c3oc3ccccc34)cc2)cc1 ; c1ccc(-c2ccc(N(c3ccc(-c4cccc5c4sc4ccccc45)cc3)c3ccc(-c4cccc5c4sc4ccccc45)cc3)cc2)cc1 ; c1ccc(N(c2ccc(-c3ccc(-c4cccc5c4sc4ccccc45)cc3)cc2)c2ccc(-c3cccc4c3sc3ccccc34)cc2)cc1]

In another exemplary embodiment, the assistant layer BIL may include a compound represented by Chemical Formula 3.

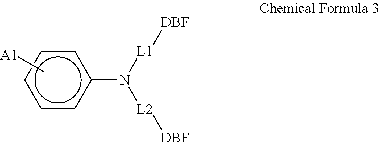

In Chemical Formula 3, A1 may be an alkyl group, an aryl group, carbazole, dibenzothiophene, or dibenzofuran (DBF), L1 and L2 may be

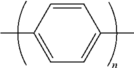

(where n is 0 to 3), and each DBF coupled or connected to L1 or L2 may, optionally, be replaced by carbazole or dibenzothiophene.

Hereinafter, a composition method (e.g., synthesis) of the assistant layer BIL according to an exemplary embodiment of the present disclosure will be described in more detail. For example, the composition method (e.g., synthesis) of the following Chemical formula 1-1 is described in more detail.

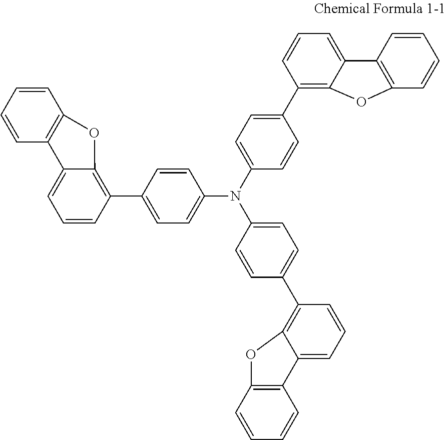 [SMILES: c1ccc2c(c1)oc1c(-c3ccc(N(c4ccc(-c5cccc6c5oc5ccccc56)cc4)c4ccc(-c5cccc6c5oc5ccccc56)cc4)cc3)cccc12]

### Composition Example

Under an argon atmosphere, 6.3 g of 4-dibenzofuran boronic acid, 4.8 g of 4,4′,4″-tribromotriphenylamine, 104 mg of tetrakis(triphenylphosphine)palladium (Pd(PPh3)4), 48 ml (2 M) of a sodium carbonate (Na2CO3) solution, and 48 ml of toluene were put in a 300 ml 3-neck flask, and reacted at 80° C. for eight hours. The reaction solution was extracted with toluene/water, and dried with anhydrous sodium sulfate. The resultant was condensed under low pressure, and 3.9 g of a yellowish-white powder was obtained through column purification of the obtained crude product.

In FIG. 4, a red resonance assistant layer R′ may be provided below the red emission layer R, and a green resonance assistant layer G′ may be provided below the green emission layer G. The red resonance assistant layer R′ and the green resonance assistant layer G′ are layers to be added in order to set a resonant distance for each color. In some embodiments, a separate resonance assistant layer provided between the hole transport layer 174 and the blue light emission layer B and the assistant layer BIL may not be formed below the blue emission layer B and the assistant layer BIL corresponding to the red emission layer R or the green emission layer G.

The above descriptions may be applied to the exemplary embodiment of FIG. 4, except for the above-described differences.

While the subject matter of this disclosure has been described in connection with what is presently considered to be practical exemplary embodiments, it is to be understood that the present disclosure is not limited to the disclosed embodiments, but, on the contrary, is intended to cover various modifications and equivalent arrangements included within the spirit and scope of the appended claims, and equivalents thereof.

What is claimed is:

1. An organic light emitting diode comprising:
a first electrode and a second electrode that face each other;
a middle layer on the first electrode;
a hole transport layer on the middle layer; and
an emission layer between the hole transport layer and the second electrode,
wherein the middle layer comprises a bipolar material formed by combining a first material comprising at least one selected from a group 1 element, a group 2 element, and a lanthanide metal, with a second material comprising a halogen element.

2. The organic light emitting diode of claim 1, wherein the middle layer comprises at least one selected from an iodinated group 1 element, an iodinated group 2 element, an iodinated lanthanide metal, and an iodinated transition metal.

3. The organic light emitting diode of claim 2, wherein the middle layer comprises at least one compound selected from LiI, NaI, KI, RbI, CsI, CuI, AgI, TlI, and CoI₂.

4. The organic light emitting diode of claim 3, wherein the thickness of the middle layer is about 10 nm to about 20 nm.

5. The organic light emitting diode of claim 4, further comprising a hole injection layer provided between the middle layer and the hole transport layer,
wherein the hole injection layer and the hole transport layer comprise an organic material.

6. The organic light emitting diode of claim 1, wherein a work function of the first electrode is about 5.0 eV to about 7.0 eV.

7. The organic light emitting diode of claim 6, wherein a work function difference between the first electrode and the hole transport layer is less than or equal to about 0.5 eV.

8. An organic light emitting diode display comprising:
a substrate;
a thin film transistor on the substrate; and
an organic light emitting diode coupled to the thin film transistor,
wherein the organic light emitting diode comprises:
a first electrode and a second electrode facing each other;
a middle layer on the first electrode;
a hole transport layer on the middle layer; and
an emission layer on the hole transport layer,
wherein the middle layer comprises a bipolar material formed by combining a first material comprising at least one selected from a group 1 element, a group 2 element, and a lanthanide metal, with a second material comprising a halogen element.

9. The organic light emitting diode display of claim 8, wherein the middle layer comprises at least one selected from an iodinated group 1 element, an iodinated group 2 element, an iodinated lanthanide metal, and an iodinated transition metal.

10. The organic light emitting diode display of claim 8, wherein a work function of the first electrode is about 5.0 eV to about 7.0 eV.

11. The organic light emitting diode display of claim 10, wherein a work function difference between the first electrode and the hole transport layer is less than or equal to about 0.5 eV.

12. The organic light emitting diode display of claim 8, further comprising a hole injection layer between the middle layer and the hole transport layer,
wherein the hole injection layer and the hole transport layer each comprise an organic material.

13. The organic light emitting diode display of claim 8, wherein the emission layer comprises a red emission layer, a green emission layer, and a blue emission layer, and further comprises an assistant layer at a lower end of the blue emission layer.

14. The organic light emitting diode display of claim 13, further comprising a red resonance assistant layer at a lower end of the red emission layer and a green resonance assistant layer at a lower end of the green emission layer.

15. The organic light emitting diode display of claim 13, wherein the assistant layer comprises a compound represented by Chemical Formula 1: 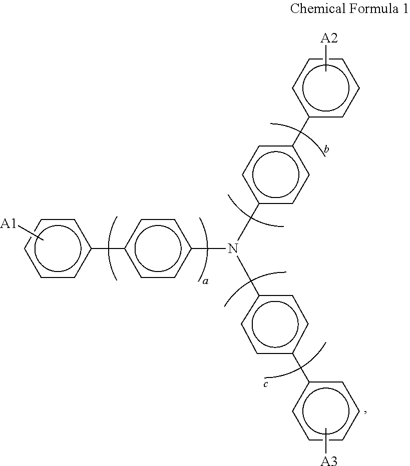
wherein, in Chemical Formula 1, A1, A2, and A3 are each independently selected from an alkyl group, an aryl group, carbazole, dibenzothiophene, dibenzofuran (DBF), and biphenyl, and a, b, and c are each independently selected from positive numbers of zero to four.

16. The organic light emitting diode display of claim 13, wherein the assistant layer comprises a compound represented by Chemical Formula 2: 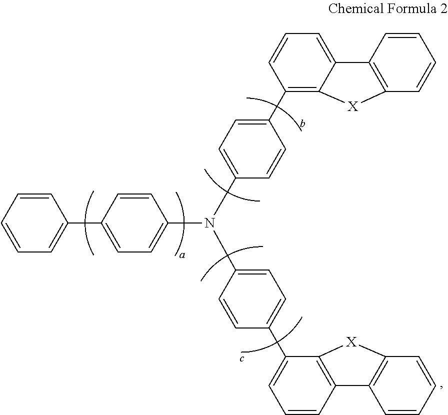
wherein, in Chemical Formula 2, a is selected from 0 to 3, and b and c are each independently selected from 0 to 3, X is selected from O, N, or S, and each X is the same as or different from each other.
